(19) United States
(12) Patent Application Publication
(10) Pub. No.: US 2018/0226433 A1
(43) Pub. Date: Aug. 9, 2018

(54) DISPLAY DEVICE AND METHOD FOR MANUFACTURING DISPLAY DEVICE

(71) Applicant: Mitsubishi Electric Corporation, Tokyo (JP)

(72) Inventors: Soshi Honda, Kumamoto (JP); Toshihiko Iwasaka, Kumamoto (JP)

(73) Assignee: Mitsubishi Electric Corporation, Tokyo (JP)

(21) Appl. No.: 15/875,107

(22) Filed: Jan. 19, 2018

(30) Foreign Application Priority Data
Feb. 7, 2017 (JP) 2017-020192

(51) Int. Cl. H01L 27/12; H01L 29/786; H01L 29/66; H01L 29/24; G02F 1/1368; G02F 1/1362

(52) U.S. Cl. CPC H01L 27/1225; H01L 29/7869; H01L 29/66969; H01L 29/24; H01L 27/1262; G02F 2201/56; G02F 1/1368; G02F 1/136286; H01L 27/124; G02F 2001/136295; G02F 2202/10; H01L 27/127

(57) ABSTRACT

A display device includes a common electrode provided to cross over the boundary between a display region and a non-display region. The common electrode is a member used for displaying an image in cooperation with a pixel electrode. In the common electrode, a portion existing at the display region is a conductor part. The conductor part is an altered part of an oxide semiconductor film.

### BACKGROUND OF THE INVENTION

### Field of the Invention

The present invention relates to a display device using an oxide semiconductor film, and a method for manufacturing the display device.

### Description of the Background Art

In general, a liquid crystal panel included in a liquid crystal display device (a liquid crystal display), which is an exemplary display device, includes an array substrate. The array substrate includes a thin film transistor (TFT), and a pixel electrode connected to the TFT. The liquid crystal panel further includes an opposite substrate (a CF substrate) that opposes to the array substrate. On the opposite substrate, a common electrode, a resin film and the like are formed. The array substrate and the opposite substrate are bonded to each other with a sealing member. The sealing member is formed to surround a display region. The shape of the sealing member is closed loop-like (frame-like).

Liquid crystal is enclosed in the space formed by the array substrate, the opposite substrate, and the sealing member. On the array substrate, a drive IC, FPCs (Flexible Printed Circuits) and the like are mounted. Note that, a liquid crystal display device is structured by the liquid crystal panel structured as described above, a bezel, a backlight unit and the like.

Recent years have seen an expansion of variety of size and resolution of the screen (the display region) of liquid crystal display devices. The resolution of the screen is, for example, the resolution within a range of VGA to QXGA. Accordingly, a wide selection of liquid crystal display devices is available. However, the size of the display region (the screen) structured by a plurality of pixels in each liquid crystal display device cannot be changed.

Note that, the shape of the display region of liquid crystal display devices (liquid crystal panels) is generally quadrangle. However, in recent years, liquid crystal panels having a non-quadrangular display region (variant panels) are also going into production. The non-quadrangular shape is, for example, a polygonal shape, a circular shape, an oval shape and the like. Hereinafter, pixels positioned at the boundary between the display region and the non-display region are also referred to as the “boundary pixels”.

When the shape of the display region is non-quadrangular, three boundary pixels such as RGB may differ from one another in the area in the display region. In this case, there exists a problem that the three boundary pixels differ from one another in the color contrast.

Japanese Patent Application Nos. 2008-216356 and 2016-085448 each disclose a technique for solving the problem (hereinafter also referred to as “Related Art A”). In Related Art A, the non-display region of each of the boundary pixels is light-shielded by a BM (a black matrix) so that the boundary pixels become identical to one another in the area in the display region.

Further, Japanese Patent Application No. 2010-286825 discloses other technique for solving the problem (hereinafter also referred to as “Related Art B”). Specifically, in Related Art B, pixels at the circumferential part of the display region differ in the extending direction from pixels at the display region.

Recent years have seen an increase in the number of display devices using an oxide semiconductor film as a member for displaying an image, for the purpose of reducing power consumption and the like. Further, as described above, recently, display devices having a non-quadrangular display region are going into production. Accordingly, there exists a demand for display devices having the structure using, at the boundary between a non-quadrangular display region and a non-display region, an oxide semiconductor film as a member for displaying an image.

### SUMMARY

An object of the present invention is to provide a display device having the structure using, at the boundary between the display region and the non-display region, an oxide semiconductor film as a member for displaying an image.

A display device according to one aspect of the present invention includes a non-quadrangular display region for displaying an image and a non-display region provided around the display region. The display device includes an electrode, and a member provided to cross over the boundary between the display region and the non-display region. The member is a member used for displaying the image in cooperation with the electrode. In the member, a portion existing at the display region is a conductor. The conductor is an altered part of an oxide semiconductor film.

The present invention provides a display device including a member provided to cross over the boundary between the display region and the non-display region. The member is a member used for displaying the image in cooperation with the electrode. In the member, a portion existing at the display region is a conductor. The conductor is an altered part of an oxide semiconductor film.

Thus, the present invention provides the display device having the structure using, at the boundary between the display region and the non-display region, an oxide semiconductor film as a member used for displaying an image.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a section view of a display device according to a first preferred embodiment of the present invention;

FIG. 2 is a plan view showing the structure of a substrate included in a display device according to the first preferred embodiment of the present invention;

FIGS. 3A and 3B are diagrams for describing the structure of a pixel arrangement region according to the first preferred embodiment of the present invention;

FIG. 4 is an enlarged view near a boundary pixel included in a display panel according to the first preferred embodiment of the present invention;

FIG. 5 is a section view of the display panel taken along line A1-A2 in FIG. 4;

FIG. 6 is an enlarged view of part of FIG. 5;

FIG. 7 is a section view of the display panel taken along line C1-C2 in FIG. 4;

FIG. 8 is a flowchart showing main steps in a method for manufacturing the display device according to the first preferred embodiment of the present invention;

FIGS. 9A to 12D are each a diagram for describing the method for manufacturing the display device according to the first preferred embodiment of the present invention;

FIGS. 13A to 13D are diagrams for describing a method for manufacturing a display device according to a first variation of the first preferred embodiment of the present invention; and

FIGS. 14A and 14B are diagrams for describing Comparative Structure J.

### DESCRIPTION OF THE PREFERRED EMBODIMENT

In the following, with reference to the drawings, a description will be given of a preferred embodiment of the present invention. In the drawings referred to in the following, an identical constituent is denoted by an identical reference character. The name and function of constituents denoted by an identical reference character are the same. Accordingly, a detailed description of part of the constituents denoted by an identical reference character may be omitted.

Note that, the dimension, material, shape, and relative position of constituents exemplarily shown in the preferred embodiment may be changed as appropriate according to the structure of a device to which the present invention is applied, various conditions and the like. Further, the dimension of constituents shown in the drawings may not be the actual dimension.

### First Preferred Embodiment

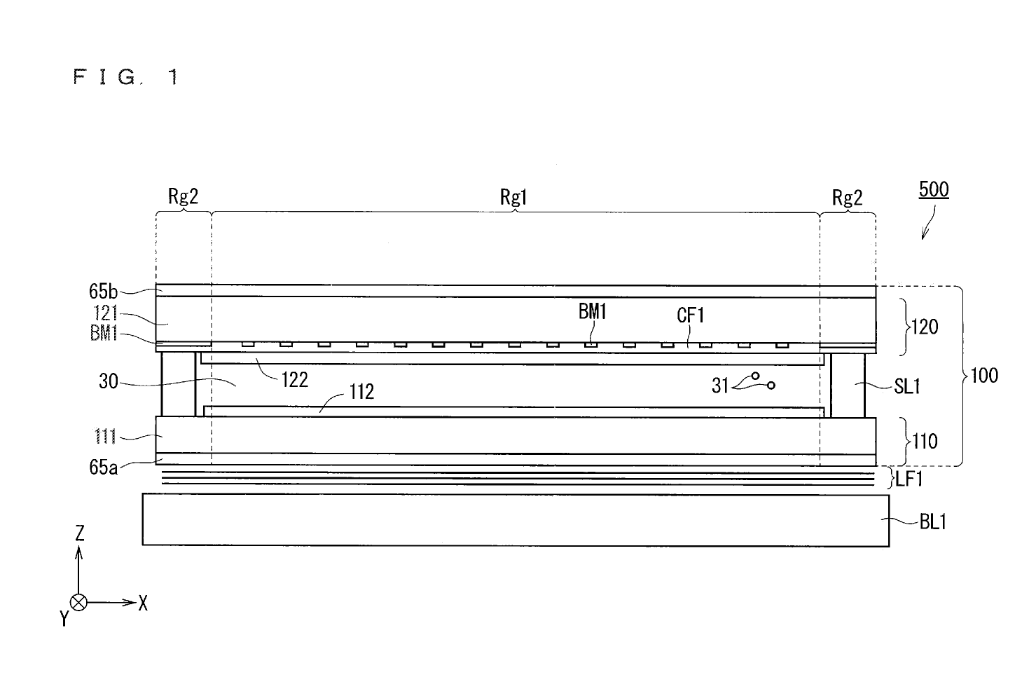

FIG. 1 is a section view of a display device 500 according to a first preferred embodiment of the present invention. The display device 500 is, as an example, an active-matrix liquid crystal display device. Further, the display device 500 is, as an example, a liquid crystal display device of the FFS (Fringe Field Switching) mode. Note that, the display device 500 is not limited to the FFS mode, and may be a liquid crystal display device of other mode applicable to the normally black mode.

In FIG. 1, X direction, Y direction, and Z direction are perpendicular to one another. In the subsequent drawings also, X direction, Y direction, and Z direction are perpendicular to one another. Hereinafter, a direction that includes X direction and a direction opposite to X direction (the −X direction) is also referred to as “X-axis direction”. Still further, hereinafter, a direction that includes Y direction and a direction opposite to Y direction (the −Y direction) is also referred to as “Y-axis direction. Still further, hereinafter, a direction that includes Z direction and a direction opposite to Z direction (−Z direction) is also referred to as “Z-axis direction”.

Further, hereinafter, a plane that includes X-axis direction and Y-axis direction is also referred to as “XY plane”. Still further, hereinafter, a plane that includes X-axis direction and Z-axis direction is also referred to as “XZ plane”. Still further, hereinafter, a plane that includes Y-axis direction and Z-axis direction is also referred to as “YZ plane”.

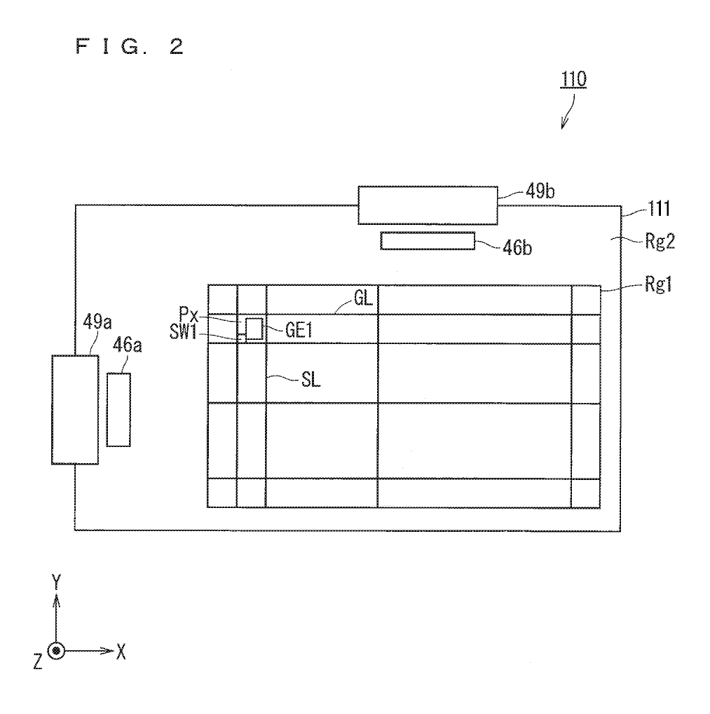

FIG. 2 is a plan view showing the structure of a substrate 110, which will be described later, included in the display device 500 according to the first preferred embodiment of the present invention. With reference to FIGS. 1 and 2, the display device 500 includes a display panel 100, a backlight unit BL1, and an optical film LF1.

The display panel 100 is a panel for displaying an image. The display panel 100 according to the present preferred embodiment is, as an example, an FFS mode-liquid crystal display panel.

The backlight unit BL1 emits light in order for the display panel 100 to display an image. The display panel 100 displays an image using light emitted by the backlight unit BL1.

The display panel 100 includes substrates 110, 120, and a liquid crystal layer 30. Each of the substrates 110, 120 is light-transmissive. The substrate 110 is an array substrate having a structure for controlling the liquid crystal layer 30. The substrate 120 is a color filter substrate that turns light transmitting through the substrate 120 into color light and emits the color light. The color light is, for example, red-color light, green-color light, blue-color light or the like.

The substrate 110 and the substrate 120 are bonded to each other with a sealing member SL1. The substrate 120 is the opposite substrate that opposes to the substrate 110. The liquid crystal layer 30 includes a plurality of liquid crystal molecules 31. Note that, while FIG. 1 shows just two liquid crystal molecules 31 for the sake of easier visual recognition of the structure, the liquid crystal layer 30 includes numerous liquid crystal molecules 31. In the region (space) formed by the substrate 110, the substrate 120, and the sealing member SL1, the liquid crystal layer 30 is enclosed.

The display panel 100 includes a pixel arrangement region Rg1 and a peripheral region Rg2. The pixel arrangement region Rg1 includes a plurality of pixel units Pu (not shown) arranged in a matrix as seen in a plan view (XY plane). Each of the pixel units Pu is structured by a red-color pixel, a green-color pixel, and a blue-color pixel. Hereinafter, each of the red-color pixel, the green-color pixel, and the blue-color pixel structuring the pixel unit Pu is also referred to as the “pixel Px” or the “pixel”.

The peripheral region Rg2 is provided at the periphery of the pixel arrangement region Rg1 as seen in a plan view (XY plane). Specifically, the peripheral region Rg2 is the region surrounding the pixel arrangement region Rg1 as seen in a plan view (XY plane). The shape of the peripheral region Rg2 as seen in a plan view (XY plane) is closed loop-like.

Note that, the pixel arrangement region Rg1 and the peripheral region Rg2 are also applied to the space where the display panel 100 is structured and to XY plane, XZ plane, and YZ plane in the space, similarly to the display panel 100.

That is, the pixel arrangement region Rg1 and the peripheral region Rg2 are applied also to each of the constituents (the substrates 110, 120, the liquid crystal layer 30 and the like) structuring the display panel 100, similarly to the display panel 100. Accordingly, for example, as shown in FIGS. 1 and 2, the substrate 110 of the display panel 100 includes the pixel arrangement region Rg1 and the peripheral region Rg2 (the rim region).

Next, a detailed description will be given of the substrate 110 as an array substrate. With reference to FIGS. 1 and 2, the substrate 110 includes a plurality of gate lines GL, a plurality of source lines SL, a substrate 111, a plurality of switching elements SW1, a plurality of pixel electrodes GE1, a not-shown plurality of common electrodes CE1, a polarizer 65a, and an alignment film 112.

Note that, in FIG. 2, for the sake of easier understanding of the structure, four gate lines GL and four source lines SL are shown. However, practically, the substrate 110 includes n-pieces (where n is an integer of 5 or greater) of gate lines GL and s-pieces (where n is an integer of 5 or greater) of source lines SL.

While a detailed description will be given later, the gate lines GL and the source lines SL are each a line for transmitting, to corresponding one of the switching elements SW1, a signal for controlling the switching element SW1. The switching element SW1 supplies the pixel electrode GE1, which will be described later, with voltage using the signal. Note that, the quadrangle formed by a plurality of gate lines GL and a plurality of source lines SL corresponds to the “pixel Px”.

Each of the pixels Px structuring the pixel arrangement region Rg1 of the substrate 110 is provided with the switching element SW1. The substrate 111 is light-transmissive. The substrate 111 is made of an insulating material. The substrate 111 is, for example, a transparent glass substrate. On one surface of the substrate 111, a plurality of switching elements SW1 are provided.

Each of the switching elements SW1 is, for example a TFT. Specifically, each of the switching elements SW1 is, for example an N-channel type MOSFET (a Metal-Oxide-Semiconductor Field-Effect Transistor). Note that, each of the switching elements SW1 may be a P-channel type MOSFET. Each of the switching elements SW1 includes the drain electrode, the source electrode, and the gate electrode. To each of the switching elements SW1, the pixel electrode GE1 is connected. Specifically, to the drain electrode of each of the switching elements SW1, the pixel electrode GE1 is connected.

The pixel electrode GE1 is provided to each of the plurality of pixels Px structuring the pixel arrangement region Rg1. Each of the pixel electrodes GE1 is an electrode for generating an electric field in the liquid crystal layer 30, by being applied with voltage. Specifically, each of the pixel electrodes GE1 is used for generating an electric field for changing the orientation of the liquid crystal molecules 31 in the liquid crystal layer 30. The shape of each of the pixel electrodes GE1 is flat plate-like.

The plurality of common electrodes CE1 are each, as an example, elongated. Each of the common electrodes CE1 extends in the vertical direction (Y-axis direction) of the pixel arrangement region Rg1. In the pixel arrangement region Rg1, each of the common electrodes CE1 is provided across a plurality of pixels Px arranged in the vertical direction (Y-axis direction) of the pixel arrangement region Rg1.

Note that, each of the common electrodes CE1 is provided with a slit SLt, which will be described later. The slit SLt is for generating a fringe electric field between the common electrode CE1 and the pixel electrode GE1. The pixel electrode GE1 and the common electrode CE1 are each a transparent electrode. The transparent electrode is made of, for example, ITO (Indium Tin Oxide), IZO (Indium Zinc Oxide) or the like.

The alignment film 112 is for orienting the liquid crystal molecules 31. The alignment film 112 is provided at one surface of the substrate 111.

The display device 500 (the display panel 100) displays an image using the pixel electrode GE1 and the common electrode CE1. Specifically, the display device 500 (the display panel 100) applies voltage between the pixel electrode GE1 and the common electrode CE1. Thus, a fringe electric field is generated between the pixel electrode GE1 and the common electrode CE1. In response to the generation of the fringe electric field, the orientation of the liquid crystal molecules 31 changes. That is, the charges accumulated between the pixel electrode GE1 and the common electrode CE1 change the orientation of the liquid crystal molecules 31.

In response to the change in the orientation of the liquid crystal molecules 31, the liquid crystal layer 30 drives. In this manner, the display device 500 (the display panel 100) drives the liquid crystal layer 30, thereby displaying an image. Thus, the common electrode CE1 being a conductor is a member used for displaying an image in cooperation with the pixel electrode GE1 (the electrode).

Next, a detailed description will be given of the substrate 120 as a color filter substrate. With reference to FIG. 1, the substrate 120 includes a polarizer 65b, a substrate 121, a color filter CF1, a black matrix BM1, and an alignment film 122.

The substrate 121 is a light-transmissive transparent substrate. On one surface of the substrate 121, the color filter CF1 and the black matrix BM1 are provided. The black matrix BM1 is a light shielding member shielding part of light.

Next, a detailed description will be given of the electrical structure of the substrate 110. With reference to FIG. 2, at the peripheral region Rg2 of the substrate 110, a scan signal drive circuit 46a and a display signal drive circuit 46b are provided. The scan signal drive circuit 46a is connected to the gate lines GL. Further, the scan signal drive circuit 46a is connected to an external line 49a. The display signal drive circuit 46b is connected to the source lines SL. Further, the display signal drive circuit 46b is connected to an external line 49b.

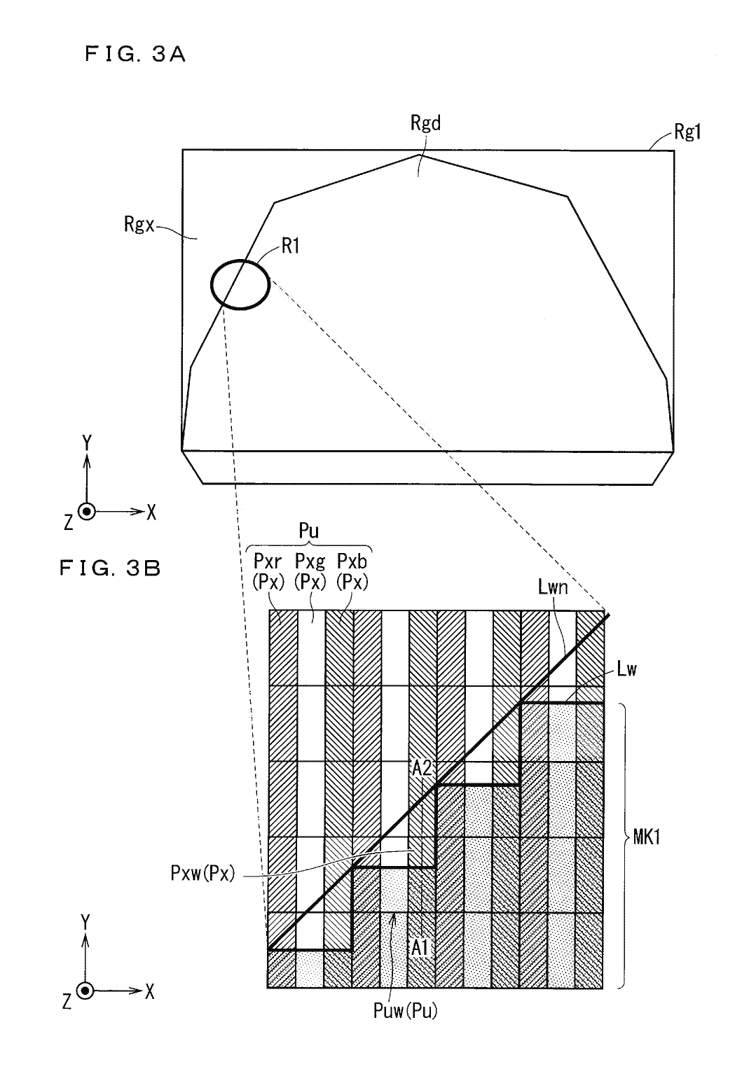

Next, a description will be given of the structure of the pixel arrangement region Rg1. FIGS. 3A and 3B are diagrams for describing the structure of the pixel arrangement region Rg1 according to the first preferred embodiment of the present invention. The pixel arrangement region Rg1 includes a display region Rgd and a non-display region Rgx. The display region Rgd is a region provided in order for the display panel 100 (the display device 500) to display an image. The non-display region Rgx is a region where no image is displayed. The non-display region Rgx is provided around the display region Rgd.

With reference to FIG. 3A, the shape of the display region Rgd is non-quadrangular. FIG. 3B is an enlarged view of a region R1 corresponding to the proximity of the boundary (the region R1) between the display region Rgd and the non-display region Rgx. FIG. 3B shows a boundary line Lw. In the present preferred embodiment, the shape of the boundary line Lw is zigzag. The boundary line Lw represents the boundary between the display region Rgd and the non-display region Rgx.

Note that, a boundary line Lwn shown in FIG. 3B roughly represents the boundary portion between the display region Rgd and the non-display region Rgx. Note that, FIG. 3B shows a photomask MK1 used in a later manufacturing step, to be referred to in a description given later. However, actually, no photomask MK1 exists at the substrate 110 of the display panel 100 when the manufacture is completed.

With reference to FIG. 3A and FIG. 3B, the pixel arrangement region Rg1 includes a plurality of pixel units Pu arranged in a matrix as seen in a plan view (XY plane). Each of the pixel units Pu is structured by pixels Pxr, Pxg, Pxb. The pixels Pxr, Pxg, Pxb are a red-color pixel, a green-color pixel, and a blue-color pixel, respectively. Each of the pixels Pxr, Pxg, Pxb is the pixel Px. That is, each of the pixel units Pu is structured by three pixels Px (the pixels Pxr, Pxg, Pxb). Accordingly, the pixel arrangement region Rg1 includes a plurality of pixels Px arranged in a matrix.

Hereinafter, the pixel unit Pu overlapping with the boundary line Lw is also referred to as the “boundary pixel unit Puw”. Further, hereinafter, the pixel Px overlapping with the boundary line Lw is also referred to as the “boundary pixel Pxw”. The boundary pixel unit Puw is structured by three boundary pixels Pxw (the pixels Pxr, Pxg, Pxb).

Hereinafter, in the boundary pixel Pxw, the portion existing at the non-display region Rgx is also referred to as the “non-display part”. Further, hereinafter, in the boundary pixel Pxw, the portion existing at the display region Rgd is also referred to as the “display part”. That is, the boundary pixel Pxw includes the non-display part and the display part.

The three boundary pixels Pxw included in each of the boundary pixel units Puw are identical to one another in the area of the non-display part. That is, the pixels Pxr, Pxg, Pxb of each of the boundary pixel units Puw are identical to one another in the area of the non-display part. Further, the three boundary pixels Pxw included in each of the boundary pixel units Puw are identical to one another in the area of the display part. That is, the pixels Pxr, Pxg, Pxb of each of the boundary pixel units Puw are identical to one another in the area of the display part.

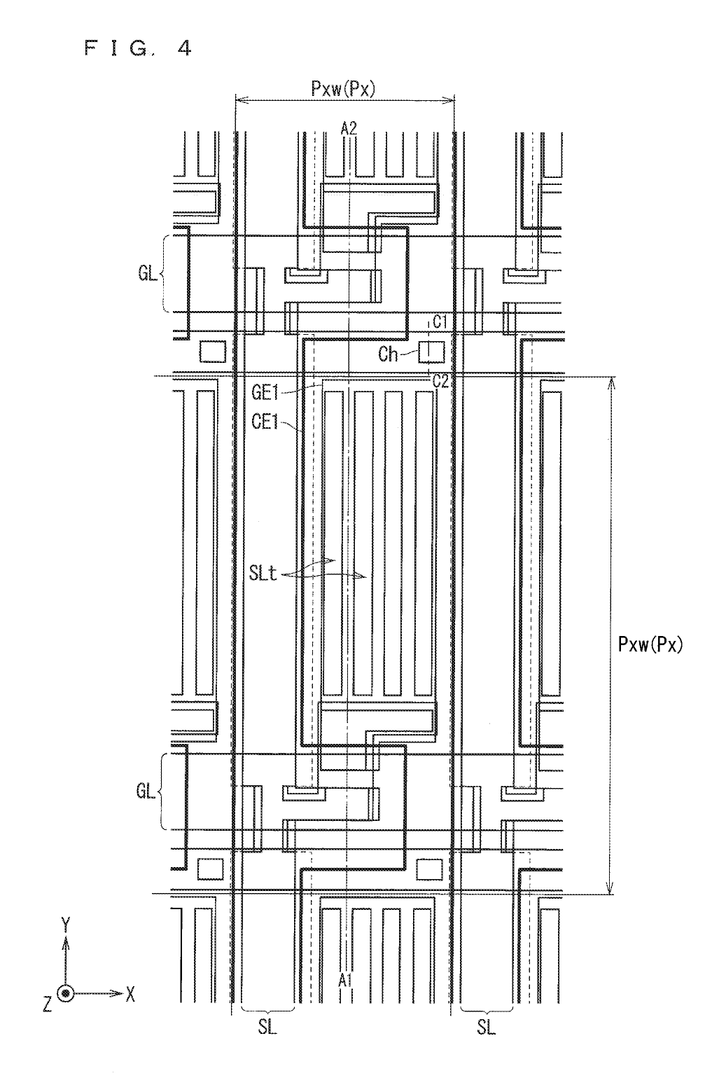

Next, a detailed description will be given of the pixel arrangement region Rg1. FIG. 4 is an enlarged view around the boundary pixel Pxw (the pixel Px) included in the display panel 100 according to the first preferred embodiment of the present invention. Note that, part of the constituents shown in FIG. 4 are shown just by their contours. For example, as to the common electrode CE1, the contour of the common electrode CE1 is represented by a bold line. Further, for example, as to the pixel electrode GE1, just the contour of the pixel electrode GE1 is shown.

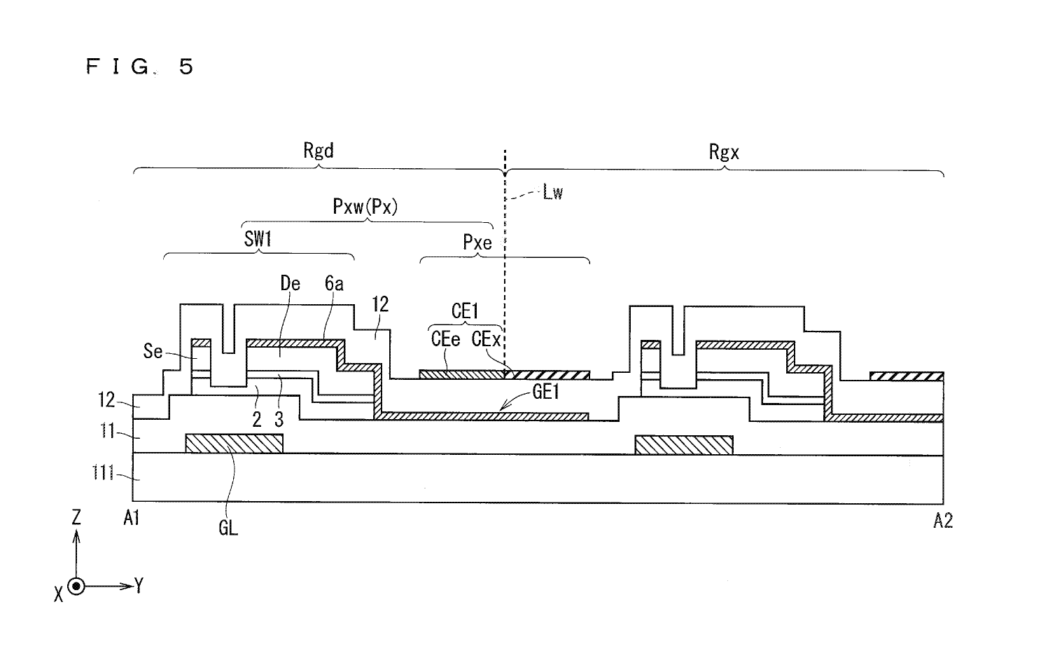

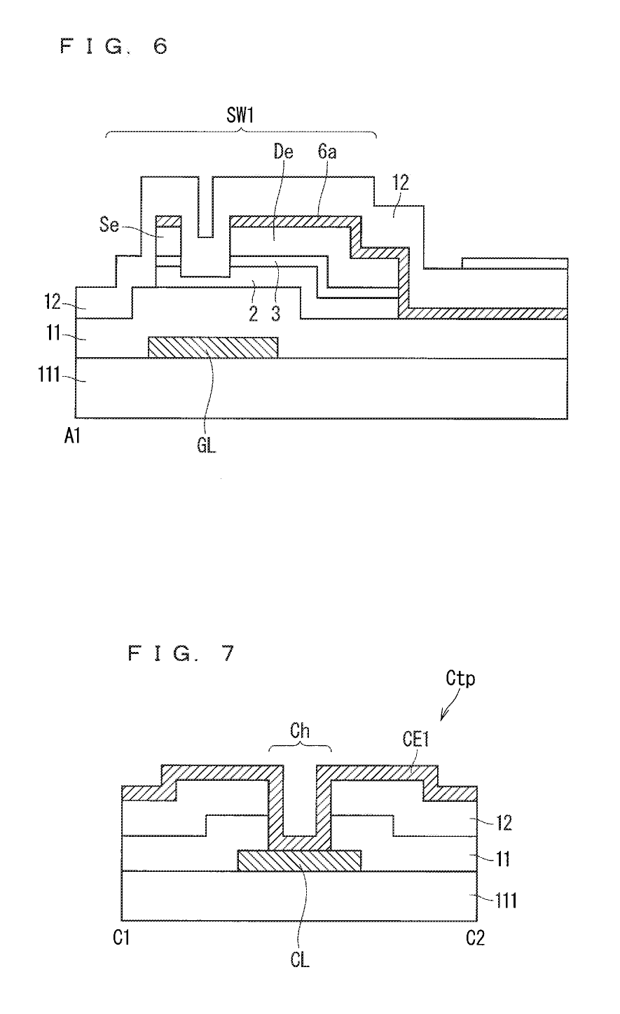

FIG. 5 is a section view of the display panel 100 taken along line A1-A2 shown in FIG. 3B and FIG. 4. FIG. 5 shows the boundary line Lw. FIG. 6 is an enlarged view of part of FIG. 5. Note that, as described above, the pixel arrangement region Rg1 includes a plurality of pixels Px arranged in a matrix.

With reference to FIG. 3B, FIGS. 4, 5, and 6, each of the pixels Px includes the switching element SW1 and a pixel electrode part Pxe.

The switching element SW1 includes the gate line GL, part of a gate insulating film 11, a semiconductor film 2, an ohmic contact film 3, a source electrode Se and a drain electrode De, and a transparent conductive film 6a.

The gate line GL is formed on the substrate 111. Note that, the gate insulating film 11 covers part of the substrate 111 and the gate line GL. The semiconductor film 2 is formed on the gate insulating film 11. The ohmic contact film 3 is formed on the semiconductor film 2. The source electrode Se and the drain electrode De are formed on the ohmic contact film 3. The transparent conductive film 6a is formed on the source electrode Se and the drain electrode De.

The pixel electrode part Pxe includes the pixel electrode GE1 and part of the common electrode CE1. The pixel electrode GE1 is formed on the gate insulating film 11. An interlayer insulating film 12 is formed between the common electrode CE1 and the pixel electrode GE1.

FIG. 7 is a section view of the display panel 100 taken along line C1-C2 in FIG. 4. FIG. 7 shows a contact part Ctp included in the display panel 100. That is, FIG. 7 is a section view of the contact part Ctp.

With reference to FIG. 7, on the substrate 111, the common line CL and the gate insulating film 11 are formed. On the gate insulating film 11, the interlayer insulating film 12 is formed. Note that, at the contact part Ctp, a contact hole Ch penetrating through the interlayer insulating film 12 and the gate insulating film 11 is formed. Further, the common electrode CE1 is provided so as to be electrically connected to the common line CL using the contact hole Ch.

Next, a description will be given of the common electrode CE1. With reference to FIG. 3A, FIG. 3B and FIG. 4, each of the common electrodes CE1 is provided, in the pixel arrangement region Rg1, across a plurality of pixels Px arranged in the vertical direction (Y-axis direction) of the pixel arrangement region Rg1. That is, the common electrode CE1 extends in the vertical direction (Y-axis direction) of the pixel arrangement region Rg1. Each of the common electrodes CE1 is a member provided so as to cross over the boundary (the boundary line Lw) between the display region Rgd and the non-display region Rgx.

As seen in a plan view (XY plane), a plurality of slits SLt are provided in the common electrode CE1 where the common electrode CE1 overlaps with one pixel Px. The shape of each of the slits SLt is, for example, elongated. The longitudinal direction of each of the slits SLt is, as an example, parallel to the extending direction (Y-axis direction) of the source line SL.

(Method for Manufacturing Display Device)

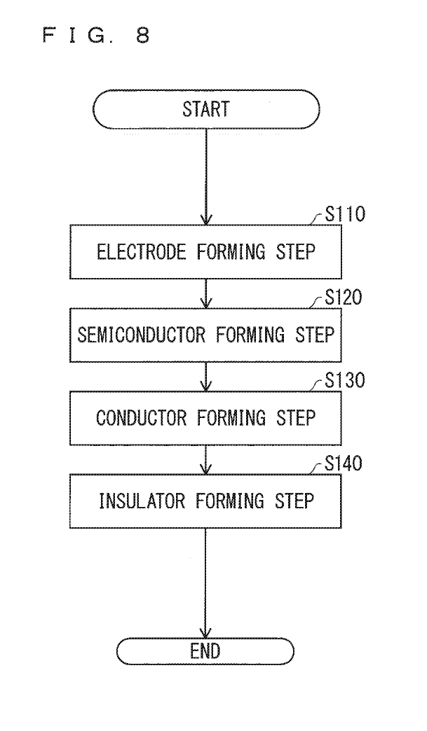

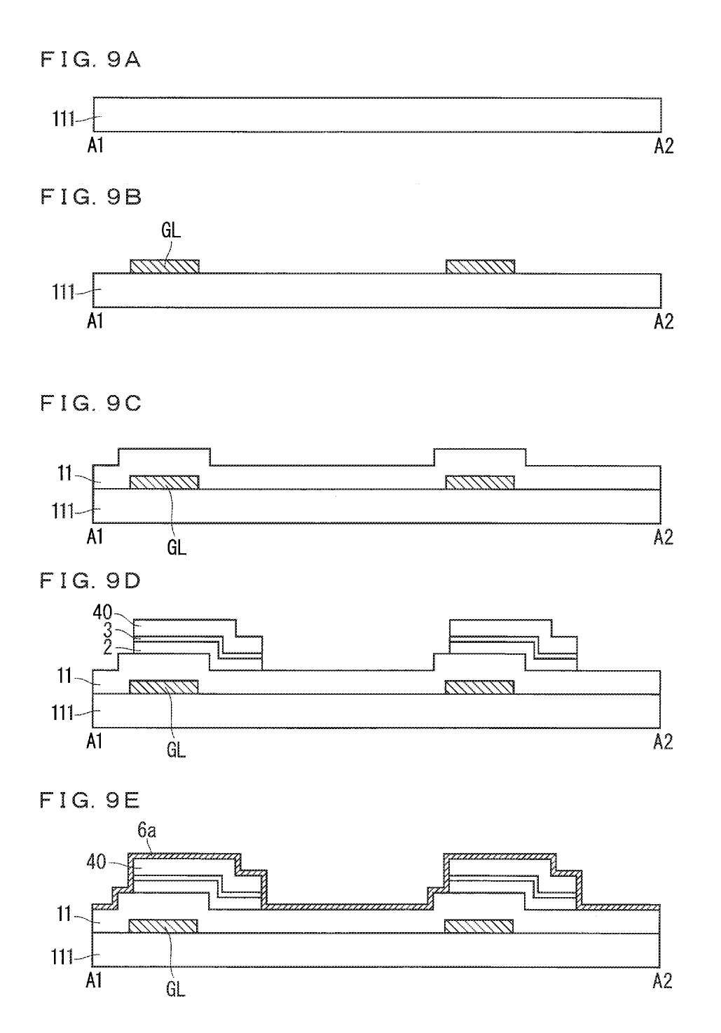

Next, a description will be given of a method for manufacturing the display device 500 (hereinafter also referred to as the “manufacturing method A”). Note that, herein, the description will be mainly given of the method for manufacturing the display panel 100, which is the main part of the display device 500, with reference to the flowchart of FIG. 8. Note that, FIG. 8 just shows main steps in the manufacturing method A. FIGS. 9A to 12D are diagrams for describing the manufacturing method A of the display device 500 (the display panel 100) according to the first preferred embodiment of the present invention.

In the manufacturing method A, firstly, the substrate 111 is provided (see FIG. 9A). Next, the first metal film is formed on the entire main surface of the substrate 111. The method of forming the first metal film is, for example, sputtering, vapor deposition or the like.

The first metal film is made of, for example, Cr, Ag, Ta, Ti, Mo, W, Ni, Cu, Au, Ag or the like. Further, the first metal film may be an alloy film whose main components are, for example, Cr, Ag, Ta, Ti, Mo, W, Ni, Cu, Au, Ag and the like. Further, the first metal film may be a layered film made of, for example, at least two materials selected from the group consisting of Cr, Ag, Ta, Ti, Mo, W, Ni, Cu, Au, and Ag.

Hereinafter, a step of forming a resist pattern is referred to as the “photolithography step”. Further, hereinafter, a step of performing patterning using the resist pattern is referred to as the “etching step”. Still further, hereinafter, a step of removing the resist pattern is referred to as the “resist removing step”.

Next, in the first photolithography step, resist is applied onto the first metal film. Then, the resist is exposed using a photomask. Thus, the resist is exposed. Next, the exposed resist is developed. Next, by patterning, a resist pattern is formed.

Next, in the first etching step, by the first metal film being etched using the resist pattern as a mask, the first metal film is patterned. Thus, the gate line GL and the common line CL are formed. Note that, the gate line GL includes the gate electrode. That is, part of the gate line GL is the gate electrode.

Next, in the first resist removing step, the resist pattern is removed. Thus, the state show FIG. 9B is attained.

Next, the gate insulating film 11, the semiconductor film 2, and the ohmic contact film 3 are layered in this order by the plasma CVD (Chemical Vapor Deposition), the atmospheric pressure CVD, the low pressure CVD or the like. Accordingly, the gate line GL and the common line CL are covered with the gate insulating film 11. Note that, FIG. 9C shows just the state where the gate insulating film 11 is formed.

The gate insulating film 11 is made of, for example, silicon nitride, silicon oxide or the like. Note that, in order to prevent short-circuiting due to occurrence of loss (a pinhole) of the film, the gate insulating film 11 is preferably formed for a plurality of times.

The semiconductor film 2 is made of, for example, amorphous silicon, polycrystalline silicon or the like. The ohmic contact film 3 is made of, for example, n-type amorphous silicon or n-type polycrystalline silicon to which a high-concentration impurity such as phosphorus (P) is added.

Next, the second metal film is formed on the ohmic contact film 3 by sputtering, vapor deposition or the like. The second metal film is made of a material similar to that of the first metal film.

Next, in the second photolithography step, a resist pattern is formed. Next, in the second etching step, by the second metal film being etched using the resist pattern as a mask, the second metal film is patterned.

Specifically, in the second etching step, the second metal film is patterned so that the source line SL and the metal film 40 are formed. The metal film 40 extends from the source line SL in the direction of a switching region. The switching region is the region where the switching element SW1 is formed by a step which will be described later. Note that, by the metal film 40 undergoing the later described step, the source electrode Se and the drain electrode De are formed.

Note that, at this time point, the second metal film (the metal film 40) exists at the portion serving as the channel region of the switching element SW1. Accordingly, the source electrode Se is connected to the drain electrode De. That is, what are formed in the second etching step are the source electrode Se and the drain electrode De being connected to each other, and the source line SL connected to the source electrode Se.

Further, in the second etching step, the ohmic contact film 3 and the semiconductor film 2 are also etched using the mask used in patterning the second metal film. Accordingly, substantially, the patterned second metal film functions as a mask. Thus, the ohmic contact film 3 and the semiconductor film 2 are patterned similarly to the second metal film.

In this manner, an identical mask is used in patterning the second metal film and in patterning the ohmic contact film 3 and the semiconductor film 2. Accordingly, the second metal film, the ohmic contact film 3, and the semiconductor film 2 can be patterned in a single-time etching step (the second etching step).

Next, in the second resist removing step, the resist pattern formed in the second photolithography step is removed. Thus, the state shown in FIG. 9D is attained.

Next, an electrode forming step is performed (S110 in FIG. 8). The electrode forming step is a step of forming the pixel electrode GE1. In the electrode forming step, firstly, the transparent conductive film 6a being the first transparent conductive film is formed over the entire uppermost surface of the member existing above the substrate 111 by sputtering or the like (see FIG. 9E). Note that, part of the transparent conductive film 6a (the first transparent conductive film) becomes the pixel electrode GE1 in a step described later. The transparent conductive film 6a is made of, for example, ITO or the like.

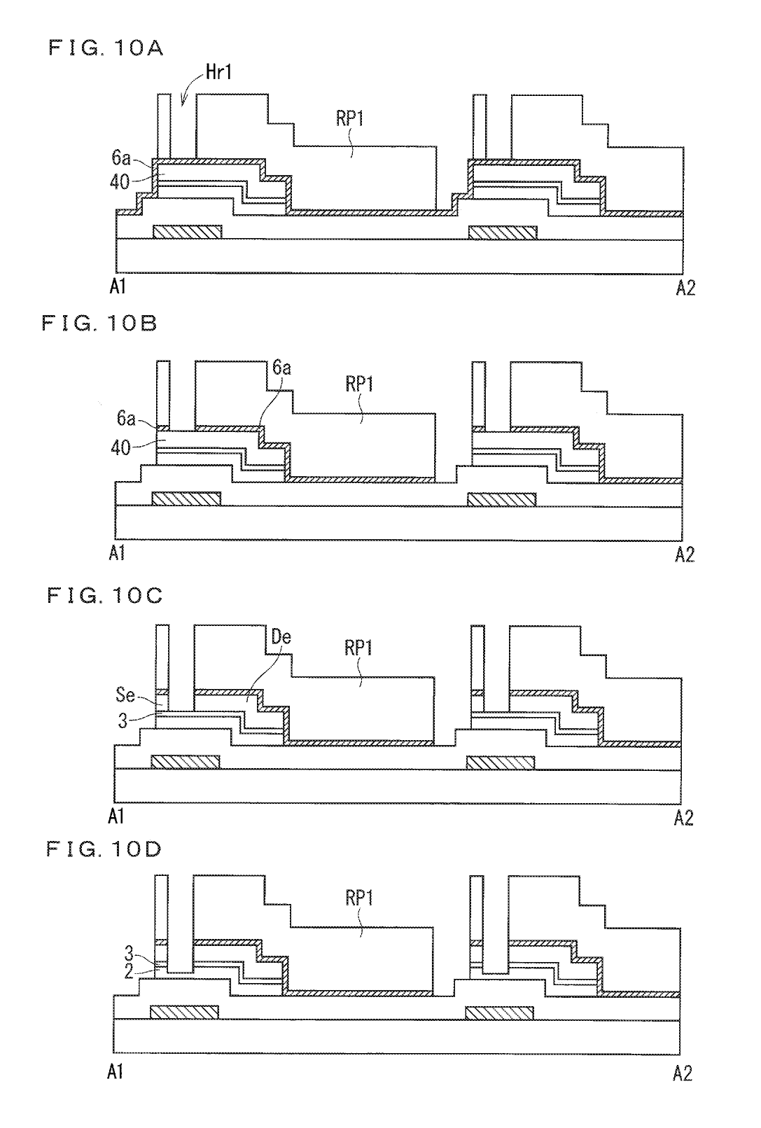

Next, in the third photolithography step, the surface of the portion in the transparent conductive film 6a, which portion is not the target of etching (removal), a resist pattern RP1 having an opening Hr1 is formed (see FIG. 10A).

Next, in the third etching step, using the resist pattern RP1 as a mask, part of the transparent conductive film 6a is etched (removed). Thus, the state shown in FIG. 10B is attained.

Next, in the metal film 40, a portion existing below the opening Hr1 of the resist pattern RP1 is removed. As a result, by the metal film 40 being separated, the source electrode Se and the drain electrode De are formed (see FIG. 10C). Further, as shown in FIG. 10D, in the ohmic contact film 3, a portion existing below the opening Hr1 of the resist pattern RP1 is removed. Thus, the portion serving as the channel region of the switching element SW1 (part of the semiconductor film 2) is exposed.

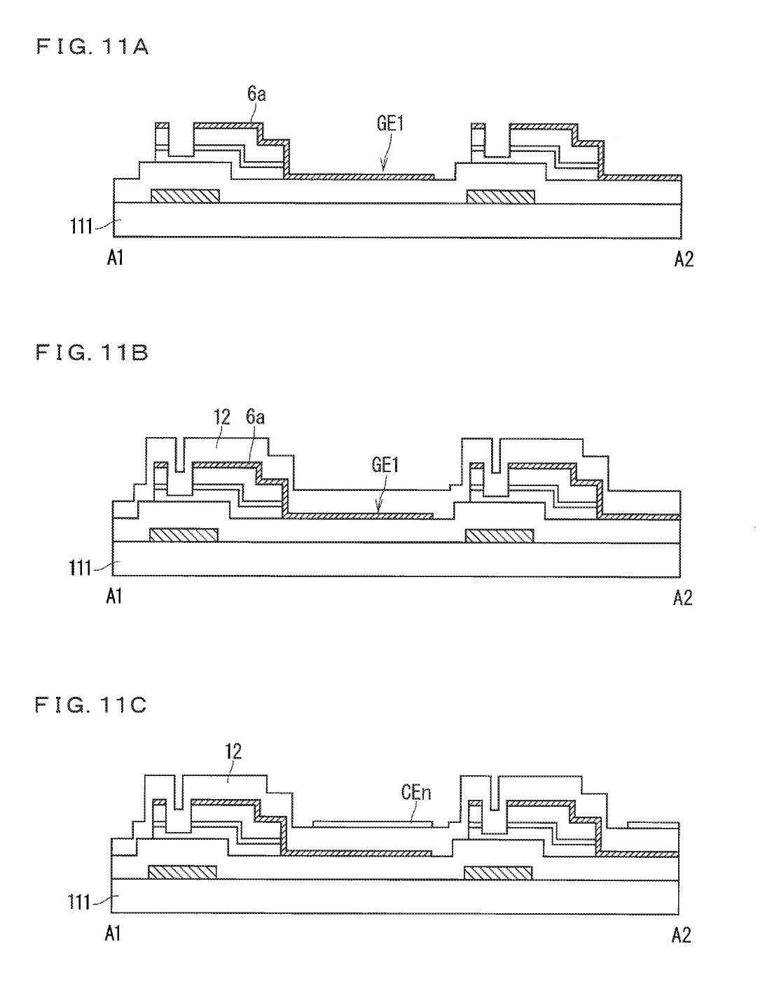

Next, in the third resist removing step, the resist pattern RP1 is removed. Thus, the pixel electrode GE1 shown in FIG. 11A is formed. The pixel electrode GE1 is part of the transparent conductive film 6a. With this step, the electrode forming step ends.

Next, as shown in FIG. 11B, the interlayer insulating film 12 (the second insulating film) is formed over the entire uppermost surface of the member existing above the substrate 111. The interlayer insulating film 12 is, for example, an SiO film. The interlayer insulating film 12 is formed by, for example, deposition using a CVD device.

Note that, the interlayer insulating film 12 is formed so that the common electrode CE1 formed in a step described later and the interlayer insulating film 12 are in contact with each other. Thus, the transparent conductive film 6a including the pixel electrode GE1 is covered with the interlayer insulating film 12. Further, the channel region of the switching element SW1 is covered with the interlayer insulating film 12.

Note that, the interlayer insulating film 12 may be structured by an inorganic insulating film and an SiO film formed on the inorganic insulating film. In this case, the thickness of the SiO film is, for example, 50 nm. Further, the inorganic insulating film is made of, for example, silicon nitride, silicon oxide or the like.

Next, by the fourth photolithography step and the fourth etching step being performed, the contact hole Ch shown in FIG. 7 is formed.

Note that, at the peripheral region Rg2 (the rim region), a gate terminal and a source terminal (not shown) are formed. The gate terminal is a terminal for connecting the gate line GL to the scan signal drive circuit 46a. The source terminal is a terminal for connecting the source line SL to the display signal drive circuit 46b. The gate terminal is formed using a wiring layer (the first metal film) which is identical to the layer where the gate line GL exists. The source terminal is formed using a wiring layer (the second metal film) which is identical to the layer where the source line SL exists.

Further, in the fourth photolithography step and the fourth etching step, a contact hole for exposing the gate terminal and the source terminal is also formed. Thereafter, in the fourth resist removing step, the resist pattern formed in the fourth photolithography step is removed.

Next, in the state shown in FIG. 11B, a semiconductor forming step is performed (S120 in FIG. 8). The semiconductor forming step is a step of forming an oxide semiconductor film. The oxide semiconductor film is a film made of an oxide semiconductor.

In the semiconductor forming step, firstly, the second transparent conductive film (an oxide semiconductor film) is formed over the entire upper surface of the interlayer insulating film 12 existing above the substrate 111 by sputtering or the like. Note that, the second transparent conductive film becomes the common electrode CE1 in a step described later. The second transparent conductive film is an oxide semiconductor film whose state is a semiconductor.

The thickness of the second transparent conductive film (the oxide semiconductor film) is, for example, 80 nm. The oxide semiconductor film is made of, for example, InGaZnO. The specific resistance of the oxide semiconductor film is, for example, about 1×10² to 1×10⁵ (Ω·cm). Hereinafter, InGaZnO is also referred to as “IGZO”.

An oxide semiconductor film whose state is a semiconductor has the characteristic in which, when the oxide semiconductor film is irradiated with a UV (UltraViolet) laser, the state of the oxide semiconductor film alters from a semiconductor into a conductor. Further, an oxide semiconductor film whose state is a conductor has the characteristic in which, when the oxide semiconductor film is irradiated with plasma containing N₂O gas, the state of the oxide semiconductor film alters from a conductor into an insulator.

Further, an oxide semiconductor film whose state is a semiconductor has the characteristic in which, when the oxide semiconductor film is irradiated with plasma containing N₂O gas, the state of the oxide semiconductor film alters from a semiconductor into an insulator. Further, an oxide semiconductor film whose state is an insulator has the characteristic in which, when the oxide semiconductor film is irradiated with the UV laser, the state of the oxide semiconductor film alters from an insulator into a conductor.

Next, by the fifth photolithography step and the fifth etching step being performed, the second transparent conductive film is patterned. Thus, as shown in FIG. 11C, the transparent conductive film CEn is formed. Note that, the transparent conductive film CEn (the oxide semiconductor film) included in the boundary pixel Pxw is provided to cross over the boundary line Lw shown in FIG. 5.

Note that, by a step described later, part of the common electrode CE1 which is the altered transparent conductive film CEn is connected to the common line CL via the contact hole Ch as shown in FIG. 7.

Note that, at the peripheral region Rg2 (the rim region), a gate terminal pad and a source terminal pad are formed. The gate terminal pad is a pad connected to the gate terminal via the contact hole. The source terminal pad is a pad connected to the source terminal via the contact hole.

Thereafter, in the fifth resist removing step, the resist pattern formed in the fifth photolithography step is removed. Thus, the state shown in FIG. 11C is achieved.

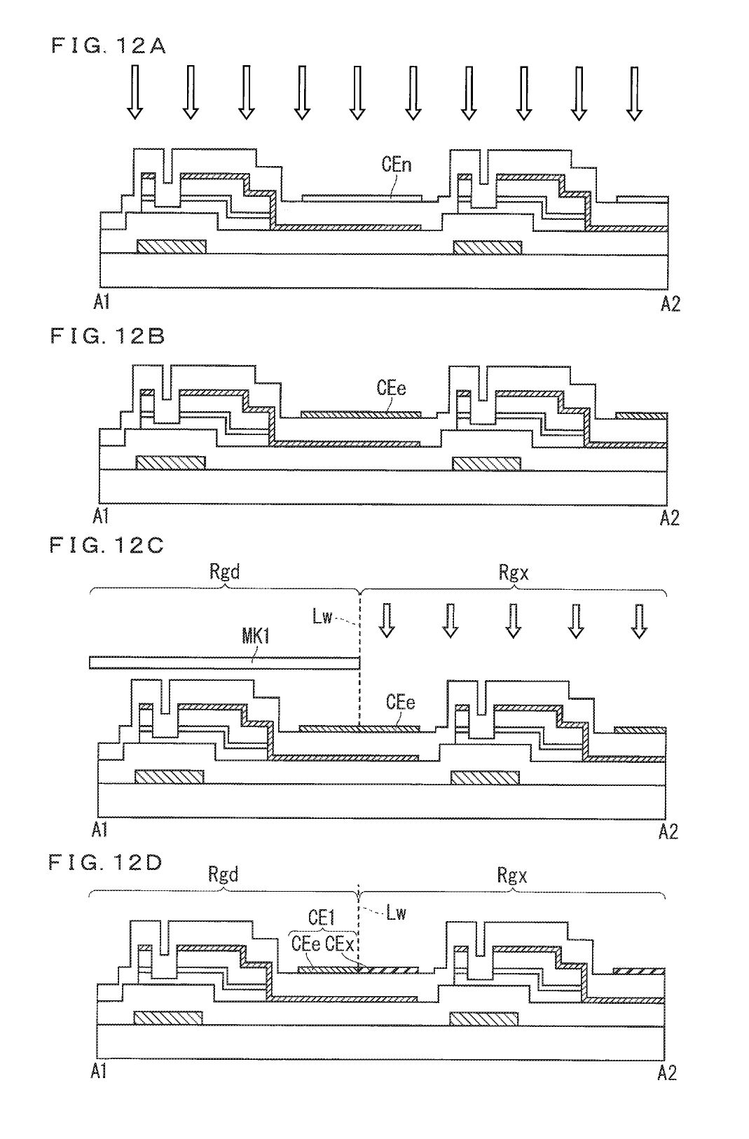

Next, a conductor forming step is performed (S130 in FIG. 8). In the conductor forming step, a laser irradiation process is performed. In the laser irradiation process, as shown in FIG. 12A, the entire uppermost surface of the member existing above the substrate 111 is irradiated with a UV laser. Thus, the oxide semiconductor film whose state is a semiconductor has its state altered from a semiconductor into a conductor. That is, the transparent conductive film CEn (the oxide semiconductor film) being in contact with the interlayer insulating film 12 (the SiO film) alters into the conductor part CEe being a conductor (see FIG. 12B). That is, the laser irradiation process is a process for altering, in the oxide semiconductor film (the transparent conductive film CEn), a portion to be formed at the display region Rgd into a conductor (the conductor part CEe).

Next, an insulator forming step is performed (S140 in FIG. 8). In the insulator forming step, a plasma process using a photomask MK1 is performed. The photomask MK1 is, for example, a photomechanical photomask. The photomask MK1 is shaped to cover the display region Rgd as seen in a plan view (XY plane).

Specifically, with reference to FIG. 3B, the photomask MK1 has a shape covering a plurality of pixels Px existing at the display region Rgd and the display part of each of the boundary pixels Pxw as seen in a plan view (XY plane). Note that, as described above, the three boundary pixels Pxw included in each of the boundary pixel units Puw are identical to one another in the area of the non-display part. Further, the three boundary pixels Pxw included in each of the boundary pixel units Puw are identical to one another in the area of the display part. That is, the three boundary pixels Pxw included in each of the boundary pixel units Puw covered with the photomask MK1 are identical to one another in the area of the display part.

In the plasma process, as shown in FIG. 3B and FIG. 12C, in the state where the display region Rgd is covered with the photomask MK1, a plasma device irradiates the non-display region Rgx with plasma containing N₂O gas. Thus, the oxide semiconductor film whose state is a conductor has its state altered from a conductor into an insulator. That is, in the conductor part CEe (the oxide semiconductor film), a portion existing at the non-display region Rgx alters into the insulator part CEx being an insulator (see FIG. 12D, FIG. 5). That is, the plasma process is a process for altering, in the oxide semiconductor film (the conductor part CEe), a portion to be formed at the non-display region Rgx into an insulator (the insulator part CEx). Note that, the specific resistance of the insulator part CEx is, for example, about 1×107 (Ω·cm).

Through the above-described conductor forming step and insulator forming step, a plurality of common electrodes CE1 are formed. Note that, each of the common electrodes CE1 includes the conductor part CEe and the insulator part CEx. The conductor part CEe exists at the display region Rgd. The insulator part CEx exists at the non-display region Rgx.

Note that, in the case where the entire pixel Px exists at the display region Rgd, the common electrode CE1 of the pixel Px includes the conductor part CEe. Further, the common electrode CE1 at the boundary pixel Pxw includes, as shown in FIG. 5, the conductor part CEe and the insulator part CEx. Note that, as described above, the common electrode CE1 is a member used for displaying an image in cooperation with the pixel electrode GE1. In the strict sense, the conductor part CEe of the common electrode CE1 is a member used for displaying an image in cooperation with the pixel electrode GE1.

The conductor part CEe included in the boundary pixel Pxw is, in the common electrode CE1, a portion existing at the display region Rgd. The conductor part CEe is part of the transparent conductive film CEn (the oxide semiconductor film) altered by the above-described laser irradiation process.

Further, as shown in FIG. 5, the common electrode CE1 is provided above the pixel electrode GE1 (the electrode). Between the common electrode CE1 and the pixel electrode GE1, the interlayer insulating film 12 (the SiO film) is provided.

Still further, the insulator part CEx included in the boundary pixel Pxw is, in the common electrode CE1, a portion existing at the non-display region Rgx. The insulator part CEx is an insulator. The insulator part CEx is other part of the conductor part CEe (the oxide semiconductor film) altered by the above-described plasma process.

Next, the substrate 110 (the array substrate) and the substrate 120 (the opposite substrate) are bonded to each other by the sealing member SL1. Next, drive ICs, FPCs and the like are mounted on the substrate 110. The drive ICs are the scan signal drive circuit 46a, the display signal drive circuit 46b and the like. Thus, the manufacture of the display panel 100 is completed.

Next, by the display panel 100, the backlight unit BL1 and the like being housed in a housing (not shown), the manufacture of the display device 500 is completed.

The display device 500 (the display panel 100) displays an image by driving the liquid crystal layer 30 by a fringe electric field generated between the pixel electrode GE1 and the common electrode CE1. Accordingly, in the boundary pixel Pxw, the non-display part corresponding to the insulator part CEx included in the common electrode CE1 does not emit light. Accordingly, the non-display part appears black. Accordingly, the present preferred embodiment can reduce the size of the display region as compared to the structure in which the common electrode CE1 included in the boundary pixel Pxw does not include the insulator part CEx.

As has been described above, in the present preferred embodiment, the display device 500 includes the common electrode CE1 provided to cross over the boundary between the display region Rgd and the non-display region Rgx. The common electrode CE1 is a member used for displaying an image in cooperation with the pixel electrode GE1. In the common electrode CE1, a portion existing at the display region Rgd is the conductor part CEe. The conductor part CEe is an altered part of the oxide semiconductor film.

Thus, the present preferred embodiment provides the display device having the structure using, at the boundary between the display region Rgd and the non-display region Rgx, an oxide semiconductor film as the member used for displaying an image.

Further, in the present preferred embodiment, the three boundary pixels Pxw included in each of the boundary pixel units Puw of the display device 500 (the display panel 100) are identical to one another in the area of the display part. Therefore, by the display part of each of the three boundary pixels Pxw included in each of the boundary pixel units Puw emitting light, in the boundary pixel unit Puw also, for example, the color contrast comparative to that exhibited by the pixel unit Pu existing at the central part of the display region Rgd can be expressed. That is, the boundary pixel units Puw corresponding to the circumferential part of the non-quadrangular display region Rgd also can evenly express the color contrast. Accordingly, the color expression state of each of the boundary pixel units Pu at the non-quadrangular display region Rgd can be maintained in an excellent manner.

Note that, other method according to which no pixels at the non-display region Rgx are driven may be removing, in the common electrode CE1, a portion existing at the non-display region Rgx. However, the above-described structure using an oxide semiconductor film is superior to the other method in being capable of eliminating any gap. That is, in the structure according to the present preferred embodiment, the common electrode CE1 is formed across the non-display region Rgx and the display region Rgd, without creating any step height. This also prevents accumulation, at such a step height, of any foreign object such as the transparent conductive film produced in a cleaning process or the like. Further, this structure also solves the problem of a tendency of the area of the transparent conductive film becoming great.

Further, in the present preferred embodiment, by changing the position of the photomask MK1 in the plasma process using the photomask MK1, the area (size) of the display region Rgd can be changed. For example, by performing the plasma process in the state where the photomask MK1 shown in FIG. 3B is shifted in −Y-direction, the display region Rgd can be reduced in size. That is, the present preferred embodiment provides the display device 500 having a display region in a variety of area using one photomask MK1.

Note that, in the above-described manufacturing method, in the third etching step, while the resist pattern RP1 formed in the third photolithography step is used as the mask for etching the transparent conductive film 6a, the metal film 40, the ohmic contact film 3, and the semiconductor film 2, the present preferred embodiment is not limited thereto. For example, the transparent conductive film 6a having undergone patterning may be used as the mask for etching the metal film 40, the ohmic contact film 3, and the semiconductor film 2.

Further, the thickness of the oxide semiconductor film (the second transparent conductive film) is not limited to 80 nm. In the case where the thickness of the oxide semiconductor film is less than 5 nm, due to the high resistance value of the whole oxide semiconductor film, the oxide semiconductor film does not function as an electrode. Accordingly, the thickness of the oxide semiconductor film should be, for example, at least 5 nm.

Note that, the upper limit value of the thickness of the oxide semiconductor film is 1 μm or less. In the case where the thickness of the oxide semiconductor film is great, a reduction in productivity of the display device is invited. Accordingly, the thickness of the oxide semiconductor film is determined as appropriate according to the specification of the display device. In general, the thickness of the oxide semiconductor film preferably falls within a range of 10 nm to 500 nm inclusive.

Further, the thickness of the SiO film is not limited to, for example, 50 nm. In the case where the thickness of the SiO film is less than 1 nm, it is difficult to attain a uniform thickness of the film and, therefore, the effect of the present invention cannot be fully exhibited. Accordingly, the thickness of the SiO film should be 1 nm or more.

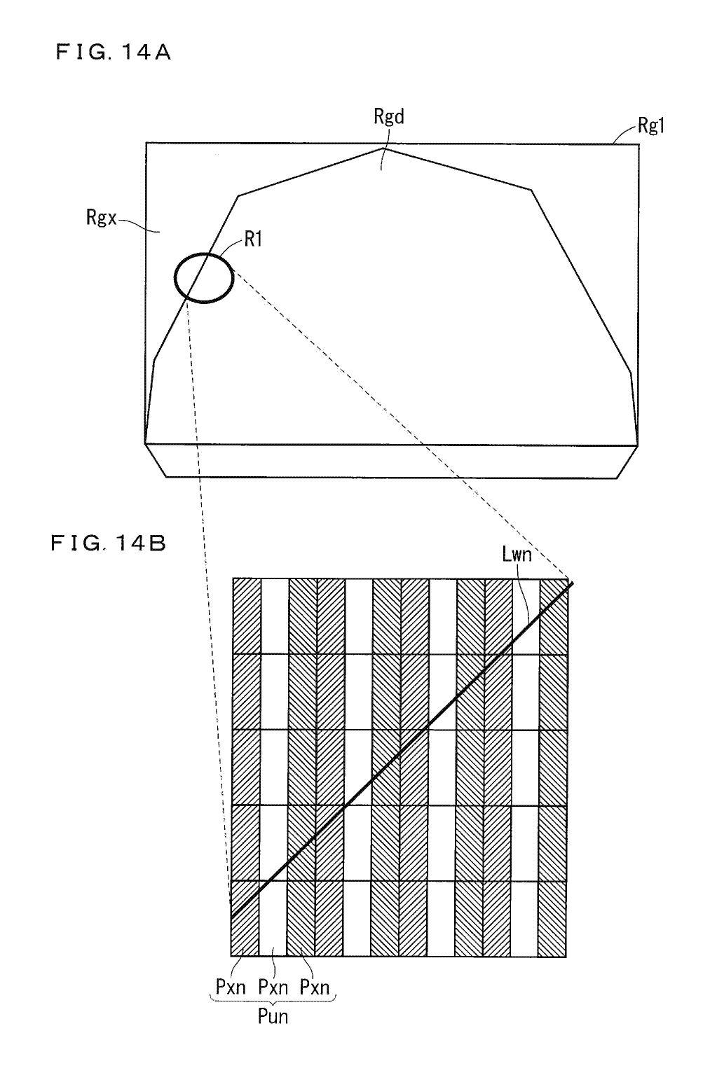

Here, the structure around the boundary line Lw according to the present preferred embodiment is compared against a structure using a black matrix (hereinafter also referred to as “Comparative Structure J”). FIGS. 14A and 14B are diagrams for describing Comparative Structure J. In Comparative Structure J, the non-display region Rgx shown in FIG. 14A is covered with a black matrix. FIG. 14B is an enlarged view of the region R1 shown in FIG. 14A. In Comparative Structure J, a boundary line Lwn shown in FIG. 14B is the line representing the boundary between the display region Rgd and the non-display region Rgx.

Hereinafter, the pixel unit Pu overlapping with the boundary line Lwn of Comparative Structure J is also referred to as the “boundary pixel unit Pun”. Further, hereinafter, the pixel Px overlapping with the boundary line Lwn of Comparative Structure J is also referred to as the “boundary pixel Pxn”. Still further, hereinafter, in the boundary pixel Pxn, the portion existing at the non-display region Rgx is also referred to as the “non-display part”. Still further, hereinafter, in the boundary pixel Pxn, the portion existing at the display region Rgd is also referred to as the “display part”.

With reference to FIG. 14B, the three boundary pixels Pxn included in each of the boundary pixel units Pun are different from one another in the area of the display part. Accordingly, Comparative Structure J has a problem that the three boundary pixels Pxn included in each of the boundary pixel units Pun differ from one another in the color contrast.

On the other hand, in the present preferred embodiment, as shown in FIG. 3B, the three boundary pixels Pxw included in each of the boundary pixel units Puw are identical to one another in the area of the display part. Accordingly, the three boundary pixels Pxn in each of the boundary pixel units Puw are identical to one another in the color contrast. Thus, the present preferred embodiment can solve the problem of Comparative Structure J.

Further, as has been described above, recent years have seen an expansion of variety of size of the screen (the display region) of liquid crystal display devices. For example, while the size of the rim region cannot be changed, the size of the display region can be reduced. Accordingly, in general, a plurality of types of photomask corresponding to a plurality of sizes of the display region are fabricated. In this case, an increase in the costs of the photomask is also incurred. Note that, the above-described Related Art A or Related Art B also suffers from the problem that, in order to address the expansion of variety of size of the screen (the display region) of liquid crystal display devices, a plurality of types of photomask must be newly fabricated.

In view of the foregoing, the display device 500 (the display panel 100) according to the present preferred embodiment is structured as described above. Further, the display device 500 is manufactured according to the above-described manufacturing method. Thus, the present preferred embodiment can solve the above-described problem.

### First Variation of First Preferred Embodiment

The configuration of the variation according to the present preferred embodiment corresponds to the manufacturing method according to the first preferred embodiment in which the order of steps are partially changed (hereinafter also referred to as “Configuration Ct2”). The display device in Configuration Ct2 is the display device 500 according to the first preferred embodiment. Hereinafter, the method for manufacturing the display device 500 in Configuration Ct2 is also referred to as the “manufacturing method B”. The manufacturing method B is different from the manufacturing method A according to the first preferred embodiment in the steps later than the step for forming the structure shown in FIG. 11C. Other steps of the manufacturing method B are similar to those of the manufacturing method A and, therefore, a detailed description thereof will not be repeated. In the following, a description will be given of the steps of the manufacturing method B different from those in the manufacturing method A.

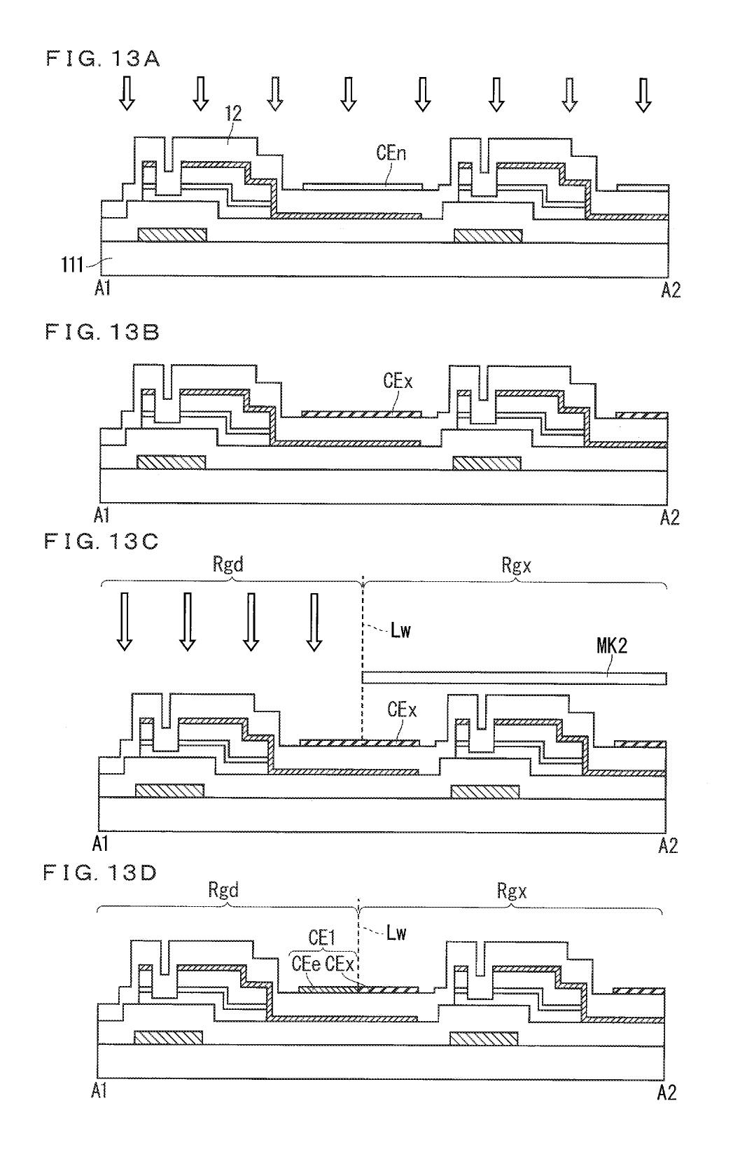

In the manufacturing method B, on the structure shown in FIG. 11C, the insulator forming step is performed. In the insulator forming step of Configuration Ct2, a plasma process B is performed. In the plasma process B, as shown in FIG. 13A, a plasma device irradiates the entire uppermost surface of a member positioned above the substrate 111 with plasma containing N₂O gas. Thus, the oxide semiconductor film whose state is a semiconductor has its state altered from a semiconductor into an insulator. That is, the transparent conductive film CEn (the oxide semiconductor film) being in contact with the interlayer insulating film 12 (the SiO film) alters into the insulator part CEx being an insulator (see FIG. 13B). That is, the plasma process B is a process for altering, in the oxide semiconductor film (the transparent conductive film CEn), the portion to be formed at the non-display region Rgx into an insulator.

Next, a conductor forming step B is performed. In the conductor forming step B, a laser irradiation process B using a photomask MK2 is performed. The photomask MK2 is shaped to cover the non-display region Rgx as seen in a plan view (XY plane).

Specifically, the photomask MK2 has a shape covering a plurality of pixels Px existing at the non-display region Rgx and the non-display part of each of the boundary pixels Pxw as seen in a plan view (XY plane). Note that, the three boundary pixels Pxw included in each of the boundary pixel units Puw covered with the photomask MK2 are identical to one another in the area of the non-display part.

In the laser irradiation process B, as shown in FIG. 13C, in the state where the non-display region Rgx is covered with the photomask MK2, the display region Rgd is irradiated with a UV laser. Thus, the oxide semiconductor film whose state is an insulator has its state altered from an insulator into a conductor. That is, in the insulator part CEx (the oxide semiconductor film), the portion existing at the display region Rgd alters into the conductor part CEe being a conductor (see FIG. 13D). That is, the laser irradiation process B is a process for altering, in the oxide semiconductor film (the insulator part CEx), the portion to be formed at the display region Rgd into a conductor (the conductor part CEe).

Next, by the steps similar to those in the first preferred embodiment being performed, the manufacture of the display panel 100 is completed. Next, by the display panel 100, the backlight unit BL1 and the like being housed in the housing (not shown), the manufacture of the display device 500 is completed.

As has been described above, the present variation in which the order of performing the plasma process and the laser irradiation process is changed also exhibits the effect similar to that exhibited by the first preferred embodiment.

In the foregoing, while the description has been given of the present invention based on the preferred embodiment and the variation, the present invention is not limited to the above-described preferred embodiment and variation. Further, various modifications and applications can be made within the scope of the spirit of the present invention. That is, as to the present invention, the preferred embodiment and the variation of the preferred embodiment can be freely combined, modified or omitted as appropriate within the scope of the invention.

For example, while it has been described that the common electrode CE1 is provided above the pixel electrode GE1, the present invention is not limited thereto. The common electrode CE1 may be provided below the pixel electrode GE1. Further, in the present preferred embodiment, as shown in FIG. 4, while a plurality of common electrodes CE1 are provided, the present invention is not limited thereto. For example, the common electrode CE1 may be one in number. In such a structure, one common electrode CE1 is provided across a plurality of pixels in the display region.

Note that, the material of the oxide semiconductor film used in the present preferred embodiment is not limited to InGaZnO. The material of the oxide semiconductor film may be, for example, any of InZnO-based, InGaO-based, InSnO-based, InSnZnO-based, InGaZnSnO-based, InAlZnO-based, InHf (hafnium) ZnO-based, InZr (zirconium) ZnO-based, InMg (magnesium) ZnO-based, and InY (yttrium) ZnO-based materials. The oxide semiconductor film made of such a material can exhibit the effect similar to that exhibited by the oxide semiconductor film made of InGaZnO.

That is, the material of the oxide semiconductor film is any of, for example, InGaZnO, InZnO, InGaO, InSnO, InSnZnO, InGaZnSnO, InAlZnO, InHfZnO, InZrZnO, InMgZnO, and InYZnO.

Further, the transparent electrode structuring the pixel electrode GE1 is not limited to ITO, and may be, for example, IZO. IZO little produces residues on the gate insulating film 11 when being etched. Accordingly, opaqueness due to residues is prevented, and the display quality of the display device 500 improves.

Still further, when the amount of residue on the gate insulating film 11 is small, the residues can be efficiently removed when dry etching is performed on the surface of the gate insulating film 11. Accordingly, the amount of residue being small is also advantageous in improving adhesion between the gate insulating film 11 and the interlayer insulating film 12. For these reasons, the transparent electrode may be made of IGZO (Indium Gallium Zinc Oxide).

Still further, while it has been described that the common electrode CE1 is provided across a plurality of pixels Px arranged in the vertical direction (Y-axis direction) of the pixel arrangement region Rg1, the present invention is not limited thereto. The common electrode CE1 corresponding to each of the pixels Px is electrically connected to the common line CL via the contact hole Ch. Accordingly, in a structure where an identical signal (voltage) is applied to portions in the common line CL respectively corresponding to the pixels Px, one common electrode CE1 may be provided to each of the pixels Px. That is, a plurality of common electrodes CE1 may be provided as being spaced apart from one another.

Still further, while it has been described that the longitudinal direction of the slit SLt is parallel to the extending direction (Y-axis direction) of the source line SL, the present invention is not limited thereto. The longitudinal direction of the slit SLt may be any direction. Further, the longitudinal direction of the slit SLt may differ for each of the common electrodes CE1 corresponding to the pixel Px, respectively. Still further, in the common electrode CE1, the portion corresponding to each of the pixels Px should be in a shape capable of, for example, generating a fringe electric field between the common electrode CE1 and the pixel electrode GE1 (e.g., comb-like).

Further, the plasma used in the plasma process or the plasma process B should be at least plasma containing N₂O gas.

Still further, the laser used in the laser irradiation process or the laser irradiation process B is not limited to a UV laser. The laser may be, for example, a UV lamp, an ultraviolet LED or the like. The laser used in the laser irradiation process may be, for example, an ultraviolet laser emitting ultraviolet light having a wavelength of 480 nm or less.

Still further, the present invention is also applicable to an array substrate other than the array substrate having the TFTs. The present invention is also applicable to, for example, an array substrate on which the pixel electrode is directly overlaid on the drain electrode of the TFT of each of the pixels.

Still further, the above-described preferred embodiment and variation include aspects of the invention at various levels, and various aspects may be made by properly combining a plurality of disclosed constituents. For example, in the case where the above-described problem can be solved and the above-described effect can be exhibited dispensing with some of the constituents disclosed in the preferred embodiment, a structure without such constituents is viable as the present invention.

While the invention has been shown and described in detail, the foregoing description is in all aspects illustrative and not restrictive. It is therefore understood that numerous modifications and variations can be devised without departing from the scope of the invention.

What is claimed is:

1. A display device including a non-quadrangular display region for displaying an image and a non-display region provided around the display region, the display device comprising:
an electrode; and
a member provided to cross over a boundary between the display region and the non-display region, wherein
the member is a member used for displaying the image in cooperation with the electrode,
in the member, a portion existing at the display region is a conductor, and
the conductor is an altered part of an oxide semiconductor film.

2. The display device according to claim 1, wherein
a portion of the member existing at the non-display region is an insulator, and
the insulator is other altered part of the oxide semiconductor film.

3. The display device according to claim 1, wherein the member is provided above or below the electrode.

4. The display device according to claim 1, wherein an SiO film is provided between the member and the electrode.

5. The display device according to claim 1, wherein a material of the oxide semiconductor film is one of InGaZnO, InZnO, InGaO, InSnO, InSnZnO, InGaZnSnO, InAlZnO, InHfZnO, InZrZnO, InMgZnO, and InYZnO.

6. A method for manufacturing a display device including a non-quadrangular display region for displaying an image and a non-display region provided around the display region, the method comprising:
forming an electrode;
forming an oxide semiconductor film provided to cross over a boundary between the display region and the non-display region; and
performing a process for altering a portion of the oxide semiconductor film into a conductor, the portion being to be formed at the display region, wherein
the conductor is a member used for displaying the image in cooperation with the electrode.

7. The method for manufacturing the display device according to claim 6, further comprising performing a process for altering a portion of the oxide semiconductor film into an insulator, the portion being to be formed at the non-display region.
